(19) United States
(12) Patent Application Publication
(10) Pub. No.: US 2021/0043864 A1
(43) Pub. Date: Feb. 11, 2021

(54) QUANTUM DOT LIGHT EMITTING DIODE DEVICE AND MANUFACTURING METHOD THEREOF

(71) Applicants: Beijing BOE Technology Development Co., Ltd., Beijing (CN); BOE TECHNOLOGY GROUP CO., LTD., Beijing (CN)

(72) Inventor: Dong LI, Beijing (CN)

(21) Appl. No.: 16/965,625

(22) PCT Filed: Dec. 18, 2019
(86) PCT No.: PCT/CN2019/126288

§ 371 Date: Jul. 29, 2020

(30) Foreign Application Priority Data
Jan. 2, 2019 (CN) 201910002903.6

(51) Int. Cl. H01L 51/50; H01L 51/56

(52) U.S. Cl. CPC H01L 51/502; H01L 51/508; H01L 51/56; H01L 51/5056; H01L 51/5092; H01L 51/5004

(57) ABSTRACT

A quantum dot light emitting diode (QLED) device and a manufacturing method thereof are provided. The QLED device includes a quantum dot light emitting layer, a first electrode, and an electron transport layer between the quantum dot light emitting layer and the first electrode. The electron transport layer has multiple electron transport sub-layers. For any two electron transport sub-layers among the multiple electron transport sub-layers, a lowest unoccupied molecular orbital (LUMO) energy level of one electron transport sub-layer close to the quantum dot light emitting layer is higher than an LUMO energy level of another electron transport sub-layer far away from the quantum dot light emitting layer, and an LUMO energy level of each of the multiple electron transport sub-layers is lower than an LUMO energy level of the quantum dot light emitting layer and higher than a work function of the first electrode.

### CROSS-REFERENCE TO RELATED APPLICATIONS

The present application claims the priority to Chinese Patent Application No. 201910002903.6 filed with the Chinese Patent Office on Jan. 2, 2019, the content of which is hereby incorporated by reference in its entirety.

### TECHNICAL FIELD

The present disclosure relates to the field of display technology, and in particular, to a quantum dot light emitting diode (QLED) device, and a manufacturing method thereof.

### BACKGROUND

A QLED device has advantages of high color gamut, self-illumination, low start-up voltage, fast response speed, and the like, and thus attracts extensive attention in the display field. A basic working principle of the QLED device is that electrons and holes are injected on both sides of a quantum dot light emitting layer, respectively, these electrons and holes recombine in the quantum dot light emitting layer to form photons, and finally light is emitted through the photons.

### SUMMARY

According to one aspect of the present disclosure, provided is a QLED device, including: a quantum dot light emitting layer; a first electrode; and an electron transport layer between the quantum dot light emitting layer and the first electrode. The electron transport layer has a plurality of electron transport sub-layers; for any two electron transport sub-layers among the plurality of electron transport sub-layers, a lowest unoccupied molecular orbital (LUMO) energy level of one electron transport sub-layer close to the quantum dot light emitting layer, is higher than an LUMO energy level of another electron transport sub-layer far away from the quantum dot light emitting layer; and an LUMO energy level of each of the plurality of electron transport sub-layers is lower than an LUMO energy level of the quantum dot light emitting layer and higher than a work function of the first electrode.

According to an embodiment of the present disclosure, an absolute value of an LUMO energy level difference between two adjacent electron transport sub-layers among the plurality of electron transport sub-layers ranges from 0.1 eV to 0.3 eV.

According to an embodiment of the present disclosure, the absolute value of the LUMO energy level difference between the two adjacent electron transport sub-layers is 0.2 eV.

According to an embodiment of the present disclosure, the plurality of electron transport sub-layers include a first electron transport sub-layer and a second electron transport sub-layer arranged in a direction perpendicular to the quantum dot light emitting layer, the first electron transport sub-layer is close to the quantum dot light emitting layer, and the second electron transport sub-layer is far away from the quantum dot light emitting layer.

According to an embodiment of the present disclosure, each of a material of the first electron transport sub-layer and a material of the second electron transport sub-layer includes one of: zinc oxide nanoparticles, magnesium-doped zinc oxide nanoparticles, aluminum-doped zinc oxide nanoparticles, and lithium-doped zinc oxide nanoparticles; and the materials of the first electron transport sub-layer and the second electron transport sub-layer are different from each other.

According to an embodiment of the present disclosure, a mass percentage of magnesium in the magnesium-doped zinc oxide nanoparticles ranges from 5% to 20%; and/or a mass percentage of aluminum in the aluminum-doped zinc oxide nanoparticles ranges from 5% to 20%; and/or a mass percentage of lithium in the lithium-doped zinc oxide nanoparticles ranges from 5% to 20%.

According to an embodiment of the present disclosure, the materials of the first electron transport sub-layer and the second electron transport sub-layer are the magnesium-doped zinc oxide nanoparticles and the zinc oxide nanoparticles, respectively; or the materials of the first electron transport sub-layer and the second electron transport sub-layer are the magnesium-doped zinc oxide nanoparticles and the aluminum-doped zinc oxide nanoparticles, respectively; or the materials of the first electron transport sub-layer and the second electron transport sub-layer are the aluminum-doped zinc oxide nanoparticles and the zinc oxide nanoparticles, respectively.

According to an embodiment of the present disclosure, when the materials of the first electron transport sub-layer and the second electron transport sub-layer are the magnesium-doped zinc oxide nanoparticles and the zinc oxide nanoparticles, respectively, the mass percentage of the magnesium in the magnesium-doped zinc oxide nanoparticles ranges from 5% to 15%.

According to an embodiment of the present disclosure, a size of the first electron transport sub-layer in the direction perpendicular to the quantum dot light emitting layer ranges from 20 nm to 30 nm.

According to an embodiment of the present disclosure, a size of the second electron transport sub-layer in the direction perpendicular to the quantum dot light emitting layer ranges from 10 nm to 20 nm.

According to an embodiment of the present disclosure, an LUMO energy level of the first electron transport sub-layer ranges from −3.6 eV to −4.2 eV.

According to an embodiment of the present disclosure, an LUMO energy level of the second electron transport sub-layer ranges from −3.8 eV to −4.2 eV.

According to an embodiment of the present disclosure, a material of the quantum dot light emitting layer includes indium phosphide.

According to an embodiment of the present disclosure, the QLED device further includes: a second electrode; a hole injection layer; and a hole transport layer. The second electrode, the hole injection layer, the hole transport layer and the quantum dot light emitting layer are sequentially stacked.

According to an embodiment of the present disclosure, respective LUMO energy levels of the hole injection layer, the hole transport layer, the quantum dot light emitting layer, the first electron transport sub-layer and the second electron transport sub-layer decrease sequentially, along a direction from the second electrode to the first electrode.

According to an embodiment of the present disclosure, the QLED device further includes a substrate. The first electrode, the second electron transport sub-layer, the first electron transport sub-layer, the quantum dot light emitting layer, the hole transport layer, the hole injection layer, and the second electrode are sequentially stacked on the substrate along a direction from the first electrode to the second electrode; or the second electrode, the hole injection layer, the hole transport layer, the quantum dot light emitting layer, the first electron transport sub-layer, the second electron transport sub-layer, and the first electrode are sequentially stacked on the substrate along a direction from the second electrode to the first electrode.

According to another aspect of the present disclosure, a method for manufacturing the above QLED device is provided, the method including forming the quantum dot light emitting layer, the electron transport layer and the first electrode on a substrate sequentially. The electron transport layer is formed to have the plurality of electron transport sub-layers; for the any two electron transport sub-layers among the plurality of electron transport sub-layers, the LUMO energy level of the electron transport sub-layer close to the quantum dot light emitting layer, is higher than the LUMO energy level of the other electron transport sub-layer far away from the quantum dot light emitting layer; and the LUMO energy level of each of the plurality of electron transport sub-layers is lower than the LUMO energy level of the quantum dot light emitting layer and higher than the work function of the first electrode.

According to an embodiment of the present disclosure, an absolute value of an LUMO energy level difference between two adjacent electron transport sub-layers among the plurality of electron transport sub-layers ranges from 0.1 eV to 0.3 eV.

According to an embodiment of the present disclosure, the method further includes: applying a reverse bias voltage between a second electrode and the first electrode to enhance orientation of anions and cations in structural layers between the second electrode and the first electrode.

### BRIEF DESCRIPTION OF THE DRAWINGS

FIG. 1a is a schematic structural diagram of a QLED device according to an embodiment of the present disclosure.

FIG. 1b is a schematic diagram of energy levels of a QLED device according to an embodiment of the present disclosure.

FIG. 2a illustrates brightness versus voltage curves of a QLED device according to an embodiment of the present disclosure and a QLED device in a related art, respectively.

FIG. 2b illustrates efficiency versus voltage curves of a QLED device according to an embodiment of the present disclosure and a QLED device in the related art, respectively.

FIG. 3a is another schematic structural diagram of a QLED device according to an embodiment of the present disclosure.

FIG. 3b is yet another schematic structural diagram of a QLED device according to an embodiment of the present disclosure.

### DETAILED DESCRIPTION

In order to enable those skilled in the art to better understand the technical solutions of the present disclosure, the present disclosure will be described below in further detail with reference to the drawings and exemplary embodiments.

The present disclosure will be described below in more detail with reference to the drawings. In the various drawings, the same elements are indicated by similar reference numerals. For clarity, various parts in the drawings may not be drawn to scale. In addition, some well-known parts may not be shown in the drawings.

In the following, many specific details of the present disclosure are described, such as structures, materials, dimensions, processes and technologies of the components, in order to understand the present disclosure more clearly. However, as those skilled in the art would understand, the technical solutions of the present disclosure may not be implemented according to these specific details.

In a QLED device in the related art, holes are transmitted into a quantum dot light emitting layer though a hole injection layer, and electrons are transmitted into the quantum dot light emitting layer though an electron transport layer. However, a mobility of electrons is not the same as that of holes. Specifically, the mobility of electrons is less than that of holes, resulting in excessive accumulation of holes in the quantum dot light emitting layer, which leads to low brightness and low efficiency of the QLED device.

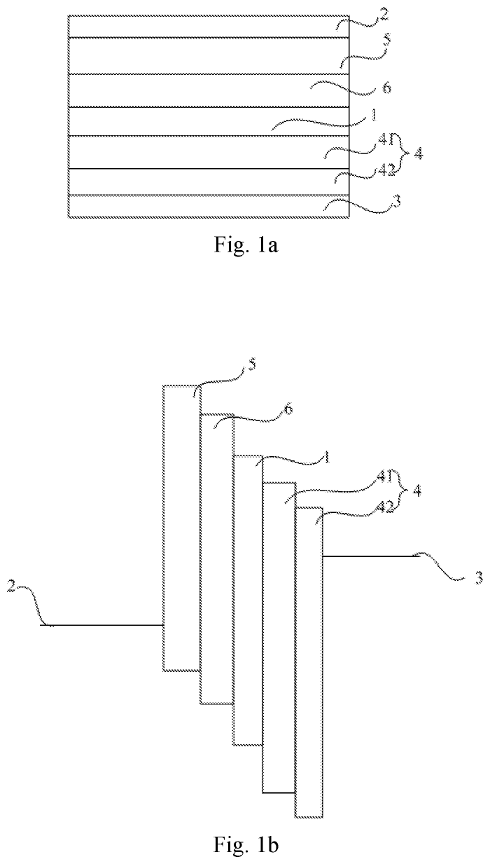

As shown in FIGS. 1a and 1b, an embodiment of the present disclosure provides a QLED device, which may include a quantum dot light emitting layer 1, a first electrode 3 and a second electrode 2 located on both sides of the quantum dot light emitting layer 1, respectively, and an electron transport layer 4 located between the quantum dot light emitting layer 1 and the first electrode 3. Two sides of the electron transport layer 4 are respectively connected to the quantum dot light emitting layer 1 and the first electrode 3. The electron transport layer 4 has at least two electron transport sub-layers. In any two of the at least two electron transport sub-layers, an LUMO energy level of one electron transport sub-layer close to (i.e., proximal to) the quantum dot light emitting layer 1, is higher than an LUMO energy level of the other electron transport sub-layer far away from (i.e., distal to) the quantum dot light emitting layer 1. LUMO energy levels of all the electron transport sub-layers are lower than an LUMO energy level of the quantum dot light emitting layer 1 and higher than a work function of the first electrode 3.

That is, a layer structure of the QLED device may include the second electrode 2, the quantum dot light emitting layer 1, the electron transport layer 4, and the first electrode 3 sequentially disposed. Specifically, the second electrode 2 may be an anode (which may be referred to as “a positive electrode”), and the first electrode 3 may be a cathode (which may be referred to as “a negative electrode”). An LUMO energy level of each electron transport sub-layer of the electron transport layer 4 is lower than the LUMO energy level of the quantum dot light emitting layer 1 and higher than the work function of the first electrode 3. This configuration may enable that electrons from the first electrode 3 are transmitted to the quantum dot light emitting layer 1 through the electron transport layer 4 with a greater mobility. The LUMO energy levels of different electron transport sub-layers in the electron transport layer 4 are different from each other, and decrease sequentially along a direction from the quantum dot light emitting layer 1 to the first electrode 3.

It should be noted that when electrons are transported in a structure having two different layers, the smaller a difference between LUMO energy levels of the two layers is, the greater the mobility of electrons is. That is, when a difference between the work function of the first electrode 3 and the LUMO level of the quantum dot light emitting layer 1 is constant, the more the number of the electron transport sub-layers included in the electron transport layer is, the smaller a difference between LUMO levels of two adjacent electron sub-transport layers through which electrons pass is, and the greater the mobility of electrons is. However, setting the electron transport layer 4 as a multilayer structure not only improves a performance of the QLED device, but also increases a complexity of manufacturing the QLED device. An excessive number (i.e., quantity) of layers in the electron transport layer 4 will adversely affect the manufacturing of the QLED device.

Therefore, in order to balance the performance of the QLED device and a simple manufacturing process, an absolute value of an LUMO energy level difference between two adjacent electron transport sub-layers among the multiple electron transport sub-layers may range from 0.1 eV to 0.3 eV. An absolute value of an LUMO energy level difference between the quantum dot light emitting layer 1 and an electron transport sub-layer adjacent to the quantum dot light emitting layer 1 may be 0.1 eV to 0.3 eV, and an absolute value of an LUMO energy level difference between the first electrode 3 and an electron transport sub-layer adjacent to the first electrode 3 may be 0.1 eV to 0.3 eV. In one example, the absolute value of the LUMO energy level difference between two adjacent electron transport sub-layers may be 0.2 eV.

According to an embodiment of the present disclosure, the energy level difference between the first electrode 3 and the electron transport sub-layer adjacent to the first electrode 3 is smaller than an energy level difference between the first electrode 3 and an electron transport layer having a single-layer structure. The energy level difference between the quantum dot light emitting layer 1 and the electron transport sub-layer adjacent to the quantum dot light emitting layer 1 is smaller than an energy level difference between the quantum dot light emitting layer 1 and the electron transport layer having the single-layer structure. Therefore, the mobility of electrons transferred from the first electrode 3 to the electron transport sub-layer adjacent to the first electrode 3 in the QLED device provided by the present disclosure, is greater than that of electrons transferred from the first electrode 3 to the electron transport layer having the single-layer structure in a QLED device of the related art. Moreover, the mobility of electrons transferred from an electron transport sub-layer to the quantum dot light emitting layer 1 in the QLED device provided by the present disclosure, is greater than that of electrons transferred from the electron transport layer having the single-layer structure to the quantum dot light emitting layer in the QLED device of the related art. Therefore, the QLED device provided by the embodiments of the present disclosure has a greater electron mobility. As a result, the mobility of electrons is equal to or substantially equal to a mobility of holes, in the QLED device provided by the embodiments of the present disclosure, thereby improving the brightness and efficiency of the QLED device.

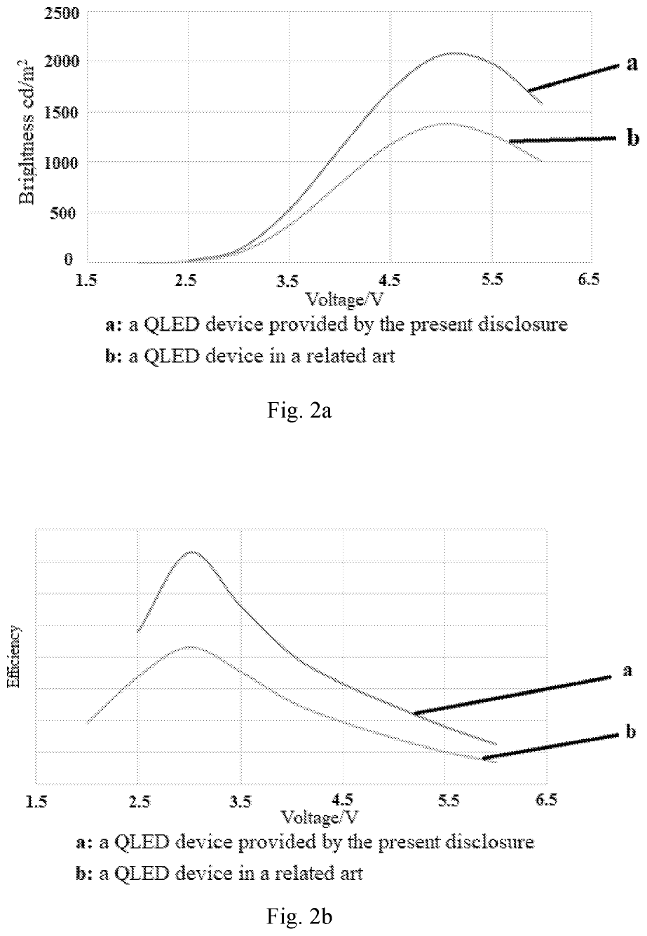

Results of experiments show that, as shown in FIGS. 2a and 2b, compared with the mobility of electrons transferred from the first electrode to the quantum dot light emitting layer through the electron transport layer merely having the single-layer structure in the related art, in the QLED provided by the embodiments of the present disclosure, when electrons are transferred from the first electrode to the quantum dot light emitting layer 1 through a plurality of electron transport sub-layers having different LUMO energy levels, the mobility of the electrons is greater, which can improve the performances of the QLED device such as luminous brightness and luminous efficiency. In FIGS. 2a and 2b, the curve a represents a related parameter curve of a QLED device provided by an embodiment of the present disclosure, and the curve b represents a related parameter curve of a QLED device of the related art. In the QLED device provided by the embodiment of the present disclosure, the electron transport layer 4 has a structure including two electron transport sub-layers, of which the electron transport sub-layer close to the quantum dot light emitting layer 1 has a thickness of 30 nm, and its material is magnesium-doped zinc oxide nanoparticles with a mass percentage of 15% of magnesium; the other electron transport sub-layer far away from the quantum dot light emitting layer 1 has a thickness of 30 nm, and its material is undoped zinc oxide nanoparticles; and a material of the first electrode 3 is aluminum. In the QLED device of the related art, the electron transport layer has a single-layer structure, and its material is undoped zinc oxide nanoparticles, a thickness of the electron transport layer is 60 nm, and a material of the first electrode is aluminum.

For example, in FIG. 2b, the ordinate (i.e., the vertical axis) represents a normalized luminous efficiency. FIG. 2b shows that the luminous efficiency of the QLED device provided by the embodiment of the present disclosure is significantly higher than that of the QLED device of the related art. For example, under a normal temperature and a driving voltage between 2.5V and 3.5V, the luminous efficiency of the QLED device provided by the embodiment of the present disclosure may be at least 60% higher than that of the QLED device of the related art.

According to an embodiment of the present disclosure, the electron transport layer 4 may include a first electron transport sub-layer 41 and a second electron transport sub-layer 42, and the first electron transport sub-layer 41 is located between the quantum dot light emitting layer 1 and the second electron transport sub-layer 42.

That is to say, the layer structure of the QLED device may include the second electrode 2, the quantum dot light emitting layer 1, the first electron transport sub-layer 41, the second electron transport sub-layer 42 and the first electrode 3 which are sequentially disposed, and an LUMO energy level of the first electron transport sub-layer 41 is higher than that of the second electron transport sub-layer 42.

According to an embodiment of the present disclosure, the electron transport layer 4 may be configured as a two-layer structure including the first electron transport sub-layer 41 and the second electron transport sub-layer 42, which can improve the performance of the QLED device while avoiding increasing the complexity of manufacturing the QLED device. It can be avoided that the excessive number of sub-layers of the electron transport layer 4 adversely affects the manufacturing of the QLED device.

According to an embodiment of the present disclosure, the first electron transport sub-layer 41 and the second electron transport sub-layer 42 may be respectively made of one of the materials: zinc oxide nanoparticles, magnesium-doped zinc oxide nanoparticles, aluminum-doped zinc oxide nanoparticles, and lithium-doped zinc oxide nanoparticles; and the materials of the first electron transport sub-layer 41 and the second electron transport sub-layer 42 are different from each other.

According to an embodiment of the present disclosure, a mass percentage of magnesium in the magnesium-doped zinc oxide nanoparticles may range from 5% to 20%, a mass percentage of aluminum in the aluminum-doped zinc oxide nanoparticles may range from 5% to 20%, and a mass percentage of lithium in the lithium-doped zinc oxide nanoparticles may range from 5% to 20%.

According to an embodiment of the present disclosure, using different materials for the first electron transport sub-layer 41 and the second electron transport sub-layer 42 enables that the LUMO energy levels of the first electron transport sub-layer 41 and the second electron transport sub-layer 42 are different from each other.

According to an embodiment of the present disclosure, the zinc oxide nanoparticles and mixtures of the zinc oxide nanoparticles and another material not only have excellent performance, but also have relatively mature preparation methods, which can reduce the manufacturing difficulty and manufacturing cost of QLED devices.

According to an embodiment of the present disclosure, the materials of the first electron transport sub-layer 41 and the second electron transport sub-layer 42 may be the magnesium-doped zinc oxide nanoparticles and the zinc oxide nanoparticles, respectively, and a mass concentration (i.e., mass percentage) of magnesium in the magnesium-doped zinc oxide nanoparticles may be 5% to 15%.

According to an embodiment of the present disclosure, the materials of the first electron transport sub-layer 41 and the second electron transport sub-layer 42 may also be the magnesium-doped zinc oxide nanoparticles and the aluminum-doped zinc oxide nanoparticles, respectively.

In other words, an LUMO energy level of an electron transport layer made of the zinc oxide nanoparticles is relatively close to an LUMO energy level of an electron transport layer made of the aluminum-doped zinc oxide nanoparticles. Therefore, the second electron transport sub-layer 42 may be made of the zinc oxide nanoparticles or the aluminum-doped zinc oxide nanoparticles, and the first electron transport sub-layer 41 may be made of the magnesium-doped zinc oxide nanoparticles. In this way, a distribution of LUMO energy levels of the first electron transport sub-layer 41 and the second electron transport sub-layer 42 may be more uniform, so that the mobility of electrons can be further improved, thereby improving the performance of the QLED device.

According to an embodiment of the present disclosure, the materials of the first electron transport sub-layer 41 and the second electron transport sub-layer 42 may be the aluminum-doped zinc oxide nanoparticles and the zinc oxide nanoparticles, respectively.

According to an embodiment of the present disclosure, a thickness of the first electron transport sub-layer 41 may be 20 nm to 30 nm, and a thickness of the second electron transport sub-layer 42 may be 10 nm to 20 nm. The above-mentioned size setting of the first electron transport sub-layer 41 and the second electron transport sub-layer 42 may further improve the mobility of electrons and performance of the QLED device.

According to an embodiment of the present disclosure, adjusting a doping concentration of the zinc oxide nanoparticle mixture and/or the thicknesses of the first electron transport sub-layer 41 and the second electron transport sub-layer 42 may enable that the LUMO energy level of the first electron transport sub-layer 41 ranges from −3.6 eV to −4.2 eV, and the LUMO energy level of the second electron transport sub-layer 42 ranges from −3.8 eV to −4.2 eV.

According to an embodiment of the present disclosure, the quantum dot light emitting layer 1 may be made of a material of indium phosphide; and alternatively, the quantum dot light emitting layer 1 may be made of other suitable materials.

According to an embodiment of the present disclosure, the QLED device may further include: a hole injection layer 5 and a hole transport layer 6 which are between the quantum dot light emitting layer 1 and the second electrode 2. In this embodiment, the hole transport layer 6 is closer to the quantum dot light emitting layer 1 than the hole injection layer 5. In addition, in the QLED device, the respective LUMO energy levels of the hole injection layer 5, the hole transport layer 6, the quantum dot light emitting layer 1, the first electron transport sub-layer 41, and the second electron transport sub-layer 42 may be decreased sequentially, along a direction from the second electrode 2 to the first electrode 3, as shown in FIG. 1b. In this way, it may be ensured that holes and electrons in the QLED device are efficiently transferred to the quantum dot light emitting layer 1, thereby improving the luminous efficiency of the QLED device. It should be noted that, in the schematic diagram of FIG. 1b, a height of a position of each layer structure may indicate a height of an energy level of the layer structure.

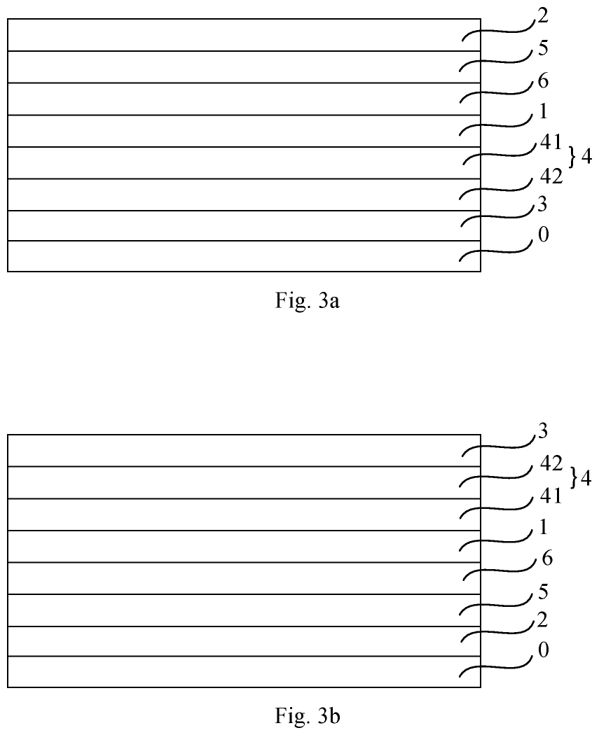

According to an embodiment of the present disclosure, as shown in FIGS. 3a and 3b that are two schematic diagrams showing other structures of the QLED device provided by the embodiments of the present disclosure. The QLED device may further include a substrate 0. In FIG. 3a, the first electrode 3, the second electron transport sub-layer 42, the first electron transport sub-layer 41, the quantum dot light emitting layer 1, the hole transport layer 6, the hole injection layer 5 and the second electrode 2 are sequentially stacked on the substrate 0, along a direction from the first electrode 3 to the second electrode 2. In FIG. 3b, the second electrode 2, the hole injection layer 5, the hole transport layer 6, the quantum dot light emitting layer 1, the first electron transport sub-layer 41, the second electron transport sub-layer 42 and the first electrode 3 are sequentially stacked on the substrate 0 along a direction from the second electrode 2 to the first electrode 3.

According to an embodiment of the present disclosure, the QLED device may be any product or component with a display function such as a display panel, electronic paper, a mobile phone, a tablet computer, a television (TV), a monitor, a notebook computer, a digital photo frame, a navigator, etc.

As shown in FIGS. 1a and 3b, an embodiment of the present disclosure also provides a method for manufacturing the QLED device provided by the embodiments of the present disclosure. The method may include steps of forming the second electrode 2, the quantum dot light emitting layer 1, the electron transport layer 4, and the first electrode 3 on the substrate 0 (not shown in FIG. 1a). Specifically, the method may include the following steps S01 to S07.

In step S01, the second electrode 2 is formed on the substrate 0.

According to an embodiment of the present disclosure, the substrate 0 may be made of glass, a flexible polyethylene terephthalate (PET) material, or other suitable materials. The second electrode 2 may be made of materials such as transparent indium tin oxide (ITO), fluorine-doped SnO₂ transparent conductive glass (FTO), or a conductive polymer. Alternatively, the second electrode 2 may also be an opaque metal electrode such as an aluminum electrode or a silver electrode.

In step S02, the hole injection layer 5 is deposited on the second electrode 2.

According to an embodiment of the present disclosure, the hole injection layer 5 may be made of an organic material, such as PEDOT:PSS (which is formed by 3,4-ethylenedioxythiophene polymer and polystyrene sulfonate), etc. Alternatively, the hole injection layer 5 may also be formed of an inorganic oxide, such as molybdenum oxide (MoOₓ).

In step S03, the hole transport layer 6 is deposited on the hole injection layer 5.

According to an embodiment of the present disclosure, the hole transport layer 6 may be made of an organic material, such as polyvinyl carbazole (PVK), N,N′-diphenyl-N,N′-disubstituted phenyl benzidine derivative (TPD), etc. The transport layer 6 may alternatively be made of an inorganic oxide, such as nickel oxide (NiOₓ), vanadium oxide (VOₓ), or the like.

In step S04, the quantum dot light emitting layer 1 is deposited and formed on the hole transport layer 6.

According to an embodiment of the present disclosure, the quantum dot light emitting layer 1 may be made of an indium phosphide (InP) material. Alternatively, the quantum dot light emitting layer 1 may also be made of other suitable materials.

In step S05, the first electron transport sub-layer 41 and the second electron transport sub-layer 42 are sequentially deposited on the quantum dot light emitting layer 1.

According to an embodiment of the present disclosure, the second electron transport sub-layer 42 may be made of the zinc oxide nanoparticles, and the first electron transport sub-layer 41 may be made of the magnesium-doped zinc oxide nanoparticles.

In step S06, the first electrode 3 is formed on the second electron transport sub-layer 42.

According to an embodiment of the present disclosure, the first electrode 3 may be a transparent electrode, such as an ITO electrode, or a thin aluminum or silver electrode, etc. The first electrode 3 may alternatively be an opaque electrode, such as a metal electrode such as an aluminum or silver electrode.

In step S07, a reverse bias voltage is applied between (or across) the second electrode 2 and the first electrode 3 to enhance orientation of anions and cations in structural layers between the second electrode 2 and the first electrode 3.

As shown in FIGS. 1a and 3a, an embodiment of the present disclosure also provides another method for manufacturing the QLED device provided by the embodiments of the present disclosure. The method may include steps of sequentially forming the first electrode 3, the electron transport layer 4, the quantum dot light emitting layer 1, and the second electrode 2 on the substrate 0 (not shown in FIG. 1a). The method may specifically include forming the first electrode 3 on the substrate 0, sequentially depositing and forming the second electron transport sub-layer 42 and the first electron transport sub-layer 41 on the first electrode 3, depositing the quantum dot light emitting layer 1 on the first electron transport sub-layer 41, sequentially depositing the hole transport layer 6 and the hole injection layer 5 on the quantum dot light emitting layer 1, and finally forming the second electrode 2 on the hole injection layer 5. A specific forming method of each layer structure is similar to the manufacturing method of the QLED device shown in FIGS. 1a and 3b, and will not be repeated here.

According to an embodiment of the present disclosure, the QLED device may be any product or component with a display function such as a display panel, electronic paper, a mobile phone, a tablet computer, a TV, a monitor, a notebook computer, a digital photo frame, navigator, etc.

It should be noted that in the present disclosure, relational terms such as first and second are used only to distinguish one entity or operation from another entity or operation, and do not necessarily require or imply that there is any actual relationship or order among these entities or operations. Moreover, the term “include”, “comprise” or any other variant thereof is intended to cover non-exclusive inclusion, so that a process, method, article, or device that includes a series of elements includes not only those elements, but also those not explicitly listed or other elements that are inherent to this process, method, article, or equipment. In the absence of more restrictions, an element defined by the clause “including the element . . . ” does not exclude that there are other identical elements in the process, method, article or equipment that includes the element.

Exemplary embodiments according to the present disclosure have been described above, these embodiments may not exhaustively describe all the details, nor limit the present disclosure to only the specific embodiments described. Obviously, according to the above description, many modifications and changes can be made. This specification selects and specifically describes these embodiments in order to better explain the principles and practical applications of the present disclosure, so that those skilled in the art can make good use of the present disclosure and modifications based on the present disclosure. The scope of the present disclosure is limited only by the appended claims and their equivalents.

1. A quantum dot light emitting diode (QLED) device, comprising:
a quantum dot light emitting layer;
a first electrode; and
an electron transport layer between the quantum dot light emitting layer and the first electrode;
wherein the electron transport layer has a plurality of electron transport sub-layers; for any two electron transport sub-layers among the plurality of electron transport sub-layers, a lowest unoccupied molecular orbital (LUMO) energy level of one electron transport sub-layer close to the quantum dot light emitting layer, is higher than an LUMO energy level of another electron transport sub-layer far away from the quantum dot light emitting layer; and an LUMO energy level of each of the plurality of electron transport sub-layers is lower than an LUMO energy level of the quantum dot light emitting layer and higher than a work function of the first electrode.

2. The QLED device according to claim 1, wherein an absolute value of an LUMO energy level difference between two adjacent electron transport sub-layers among the plurality of electron transport sub-layers ranges from 0.1 eV to 0.3 eV.

3. The QLED device according to claim 2, wherein the absolute value of the LUMO energy level difference between the two adjacent electron transport sub-layers is 0.2 eV.

4. The QLED device according to claim 1, wherein the plurality of electron transport sub-layers comprise a first electron transport sub-layer and a second electron transport sub-layer arranged in a direction perpendicular to the quantum dot light emitting layer, the first electron transport sub-layer is close to the quantum dot light emitting layer, and the second electron transport sub-layer is far away from the quantum dot light emitting layer.

5. The QLED device according to claim 4, wherein each of a material of the first electron transport sub-layer and a material of the second electron transport sub-layer comprises one of: zinc oxide nanoparticles, magnesium-doped zinc oxide nanoparticles, aluminum-doped zinc oxide nanoparticles, and lithium-doped zinc oxide nanoparticles; and the materials of the first electron transport sub-layer and the second electron transport sub-layer are different from each other.

6. The QLED device according to claim 5, wherein
a mass percentage of magnesium in the magnesium-doped zinc oxide nanoparticles ranges from 5% to 20%; and/or
a mass percentage of aluminum in the aluminum-doped zinc oxide nanoparticles ranges from 5% to 20%; and/or
a mass percentage of lithium in the lithium-doped zinc oxide nanoparticles ranges from 5% to 20%.

7. The QLED device according to claim 5, wherein
the materials of the first electron transport sub-layer and the second electron transport sub-layer are the magnesium-doped zinc oxide nanoparticles and the zinc oxide nanoparticles, respectively; or
the materials of the first electron transport sub-layer and the second electron transport sub-layer are the magnesium-doped zinc oxide nanoparticles and the aluminum-doped zinc oxide nanoparticles, respectively; or
the materials of the first electron transport sub-layer and the second electron transport sub-layer are the aluminum-doped zinc oxide nanoparticles and the zinc oxide nanoparticles, respectively.

8. The QLED device according to claim 7, wherein when the materials of the first electron transport sub-layer and the second electron transport sub-layer are the magnesium-doped zinc oxide nanoparticles and the zinc oxide nanoparticles, respectively, the mass percentage of the magnesium in the magnesium-doped zinc oxide nanoparticles ranges from 5% to 15%.

9. The QLED device according to claim 4, wherein a size of the first electron transport sub-layer in the direction perpendicular to the quantum dot light emitting layer ranges from 20 nm to 30 nm.

10. The QLED device according to claim 4, wherein a size of the second electron transport sub-layer in the direction perpendicular to the quantum dot light emitting layer ranges from 10 nm to 20 nm.

11. The QLED device according to claim 4, wherein an LUMO energy level of the first electron transport sub-layer ranges from −3.6 eV to −4.2 eV.

12. The QLED device according to claim 4, wherein an LUMO energy level of the second electron transport sub-layer ranges from −3.8 eV to −4.2 eV.

13. The QLED device according to claim 4, wherein a material of the quantum dot light emitting layer comprises indium phosphide.

14. The QLED device according to claim 4, further comprising:
a second electrode;
a hole injection layer; and
a hole transport layer;
wherein the second electrode, the hole injection layer, the hole transport layer and the quantum dot light emitting layer are sequentially stacked.

15. The QLED device according to claim 14, wherein respective LUMO energy levels of the hole injection layer, the hole transport layer, the quantum dot light emitting layer, the first electron transport sub-layer and the second electron transport sub-layer decrease sequentially, along a direction from the second electrode to the first electrode.

16. The QLED device according to claim 14, further comprising: a substrate; wherein
the first electrode, the second electron transport sub-layer, the first electron transport sub-layer, the quantum dot light emitting layer, the hole transport layer, the hole injection layer, and the second electrode are sequentially stacked on the substrate along a direction from the first electrode to the second electrode; or
the second electrode, the hole injection layer, the hole transport layer, the quantum dot light emitting layer, the first electron transport sub-layer, the second electron transport sub-layer, and the first electrode are sequentially stacked on the substrate along a direction from the second electrode to the first electrode.

17. A method for manufacturing a QLED device, the QLED device being the QLED device according to claim 1, the method comprising:
forming the quantum dot light emitting layer, the electron transport layer and the first electrode on a substrate sequentially;
wherein the electron transport layer is formed to have the plurality of electron transport sub-layers; for the any two electron transport sub-layers among the plurality of electron transport sub-layers, the LUMO energy level of the electron transport sub-layer close to the quantum dot light emitting layer, is higher than the LUMO energy level of the other electron transport sub-layer far away from the quantum dot light emitting layer; and the LUMO energy level of each of the plurality of electron transport sub-layers is lower than the LUMO energy level of the quantum dot light emitting layer and higher than the work function of the first electrode.

18. The method according to claim 17, wherein an absolute value of an LUMO energy level difference between two adjacent electron transport sub-layers among the plurality of electron transport sub-layers ranges from 0.1 eV to 0.3 eV.

19. The method according to claim 17, further comprising: applying a reverse bias voltage between a second electrode and the first electrode to enhance orientation of anions and cations in structural layers between the second electrode and the first electrode.

20. The QLED device according to claim 6, wherein
the materials of the first electron transport sub-layer and the second electron transport sub-layer are the magnesium-doped zinc oxide nanoparticles and the zinc oxide nanoparticles, respectively; or
the materials of the first electron transport sub-layer and the second electron transport sub-layer are the magnesium-doped zinc oxide nanoparticles and the aluminum-doped zinc oxide nanoparticles, respectively; or
the materials of the first electron transport sub-layer and the second electron transport sub-layer are the aluminum-doped zinc oxide nanoparticles and the zinc oxide nanoparticles, respectively.
